(19) United States
(12) Patent Application Publication
(10) Pub. No.: US 2013/0255578 A1
(43) Pub. Date: Oct. 3, 2013

(54) CHEMICAL VAPOR DEPOSITION APPARATUS HAVING SUSCEPTOR

(71) Applicant: SAMSUNG ELECTRONICS CO., LTD., Suwon-Si (KR)

(72) Inventors: Tan SAKONG, Seoul (KR); Do Young RHEE, Seoul (KR); Ki Sung KIM, Suwon (KR); Suk Ho YOON, Seoul (KR); Young Sun KIM, Suwon (KR); Sung Tae KIM, Seoul (KR)

(73) Assignee: SAMSUNG ELECTRONICS CO., LTD., Suwon-Si (KR)

(21) Appl. No.: 13/798,772

(22) Filed: Mar. 13, 2013

(30) Foreign Application Priority Data
Mar. 30, 2012 (KR) 10-2012-0033489

(51) Int. Cl. H01L 21/02

(52) U.S. Cl. CPC H01L 21/02104
USPC 118/725

(57) ABSTRACT

A chemical vapor deposition (CVD) apparatus including a chamber, a susceptor in the chamber, and a heating chamber may be provided. The susceptor includes a rotor, a rotational shaft coupled to a lower portion of the rotor, a driving device coupled to the rotational shaft, and at least one pocket defined at an upper surface of the rotor. The driving device rotatably drives the rotational shaft. The at least one pocket includes a mounting portion configured to receive a substrate thereon and a protruding portion, e.g., a convex portion, protruding from a bottom surface of the at least one pocket such that the protruding portion is positioned at a region corresponding to the rotational shaft. The heating unit surrounds the rotational shaft and heats the substrate.

### CROSS-REFERENCE TO RELATED APPLICATIONS

This application claims priority under 35. U.S.C. §119 to Korean Patent Application No. 10-2012-0033489 filed on Mar. 30, 2012, in the Korean Intellectual Property Office, the entire disclosure of which is incorporated herein by reference.

### BACKGROUND

1. Field

Example embodiments relate to a susceptor for a chemical vapor deposition apparatus, and/or a chemical vapor deposition apparatus having the same.

2. Description of the Related Art

In general, chemical vapor deposition (CVD) is used as a primary method for growing various types of crystal film on various types of substrate. Compared with a liquid phase epitaxial (LPE) method, the quality of crystals grown by the CVD method is excellent, but the speed of crystal growth is relatively slow. Thus, in order to overcome this problem, a method of growing crystal on several substrate sheets in a single growth cycle has been widely adopted.

Recently, as semiconductor devices have become finer in size and have become more efficient in performance, high-output LEDs have been developed. Generally, metal organic chemical vapor deposition (MOCVD), among various CVD techniques, has been used to manufacture the high-output LEDs. By definition, MOCVD is a kind of CVD technique, and more specifically refers to a vapor growth method for forming a compound semiconductor by depositing and attaching a metal compound on and to a semiconductor substrate by using a pyrolysis reaction of an organic metal.

In a MOCVD technique, a reactive gas supplied to the interior of a reaction chamber causes a chemical reaction on an upper surface of a heated substrate to grow an epitaxial thin film on the substrate.

The epitaxial layer is desired to have a uniform thickness across the entire region of the surface of the substrate. To achieve a uniform thickness, it is desirable to adjust a temperature to be uniform across the entire region of the substrate.

### SUMMARY

At least one embodiment provides a susceptor for a chemical vapor deposition (CVD) apparatus, which is capable of fabricating a substrate having excellent quality by preventing or reducing a temperature difference (i.e., enhancing a temperature uniformity) across the entire surface of a substrate placed on the susceptor, and/or a CVD apparatus having the same.

Also, at least one embodiment provides susceptor having a modified structure such that the number of substrates loaded thereon can be increased, thereby enhancing productivity.

According to an example embodiment, a chemical vapor deposition (CVD) apparatus includes a chamber, a susceptor in the chamber, and a heating unit. The chamber receives a reactive gas through a gas inlet to allow for deposition. The susceptor includes a rotor, a rotational shaft coupled to a lower portion of the rotor, a driving device coupled to the rotational shaft, and at least one pocket defined in an upper surface of the rotor. The driving device is configured to rotatably drive the rotational shaft. The at least one pocket includes a mounting portion configured to receive a substrate thereon and a protruding portion protruding from a bottom surface of the at least one pocket such that the protruding portion is positioned at a region corresponding to the rotational shaft. The heating unit surrounds the rotational shaft and is configured to heat the substrate. In other words, a pocket corresponding to the rotational shaft may have a portion (e.g., a convex portion) protruding from a position corresponding to the rotational shaft to uniformly transmit heat to the substrate.

An interval between a bottom surface of the pocket and the lower surface of the received substrate may be smaller at the region corresponding to the rotational shaft than regions not corresponding to the rotational shaft and being at an inner side of the mounting portion.

An upper surface of the protruding portion may be flat.

Side walls of the protruding portion may be sloped such that the interval between the lower surface of the substrate and the bottom surface of the pocket increases as the side walls get closer to a center of the pocket.

The pocket may include an annular groove portion. The annular groove portion may be formed to have a desired depth along outer edges of the mounting portion to allow the substrate disposed in the pocket to be easily separated and released therefrom.

The rotor may be a rotational structure made of graphite coated with carbon or silicon carbide (SiC).

The mounting portion may be a portion projecting from a bottom surface of the pocket.

The mounting portion may have an annular shape. A center of the mounting portion may be the same as that of the pocket.

The heating unit may be any one selected from the group consisting of an electric heater, high frequency induction heating unit, infrared radiation heating unit, and a laser.

A pocket, among the at least one pocket, under which the rotational shaft is not positioned may be formed such that an interval between a bottom surface of the pocket and the received substrate is uniform across the pocket at an inner side of the mounting portion.

A semiconductor manufacturing apparatus include a rotor, a rotational shaft, and a heating unit. The rotor includes a plurality of pockets at a first surface and the plurality of pockets includes a mounting portion configured to receive a substrate thereon. The rotational shaft is coupled to the rotor at a center portion of a second surface of the rotor, the second surface being opposite to the first surface. The rotational shaft is configured to rotate the rotor. At least one of the plurality of pockets has a protruding portion from a bottom surface of the pocket such that the protruding portion at least partially overlaps the rotational shaft in a vertical direction. The heating unit is configured to heat the substrate.

Some of the plurality of pockets may surrounds and overlaps with the rotational shaft.

An upper surface of the protruding portion may be flat.

Side walls of the protruding portion may be sloped such that an interval between the substrate and the bottom surface of the corresponding pocket increases in a direction from a center of the corresponding pocket towards the edge thereof.

Each of the plurality of pockets may have a mounting portion at an edge thereof, which is projecting from a bottom surface of the pocket.

Each of the plurality of pockets may have a groove portion at an outer edge thereof, the groove portion being positioned between the mounting portion and an edge of the pocket.

### BRIEF DESCRIPTION OF THE DRAWINGS

The above and other aspects, features and other advantages of the present inventive concepts will be more clearly understood from the following detailed description taken in conjunction with the accompanying drawings, in which:

FIG. 1 is a cross-sectional view illustrating a chemical vapor deposition (CVD) apparatus according to an example embodiment;

FIG. 2 is a plan view of a susceptor for the CVD apparatus of FIG. 1;

FIG. 3 is a cross-sectional view of the susceptor of FIG. 2 taken along line III-III′;

FIG. 4A is a cross-sectional view illustrating one of first pockets, which are spaced apart from one another in a circumferential direction, at the susceptor of FIG. 2;

FIG. 4B is an enlarged perspective view of the one first pocket of FIG. 4A;

FIG. 5A is a cross-sectional view of a second pocket disposed at a central rotation surface (defined below) of the susceptor of FIG. 2;

FIG. 5B is an enlarged perspective view of the second pocket of FIG. 5A;

FIG. 6 is a plan view of a susceptor for a CVD apparatus according to an example embodiment;

FIG. 7A is a cross-sectional view of the susceptor of FIG. 6 taken along line VII-VII′; and

FIG. 7B is an enlarged perspective view of a third pocket of the susceptor of FIG. 7A.

### DETAILED DESCRIPTION OF THE PREFERRED EMBODIMENT

A susceptor for a chemical vapor deposition (CVD) apparatus and/or a CVD apparatus having the same according to example embodiments will now be described in detail with reference to the accompanying drawings. The invention may, however, be embodied in many different forms and should not be construed as being limited to the embodiments set forth herein.

Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

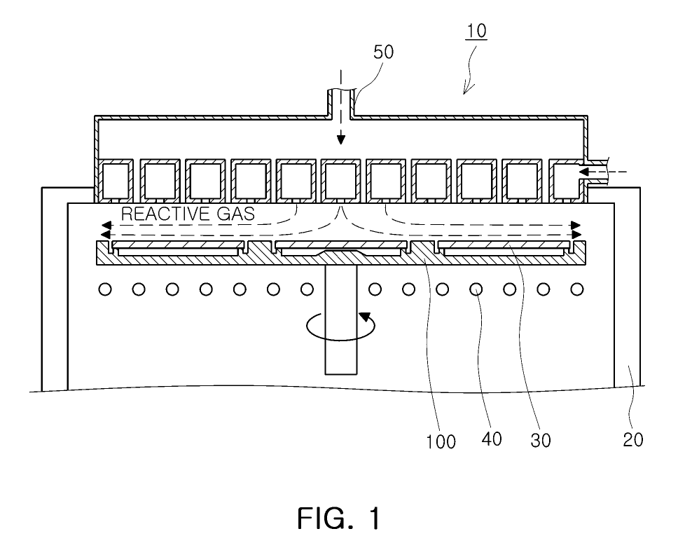

FIG. 1 is a cross-sectional view illustrating a chemical vapor deposition (CVD) apparatus according to an example embodiment.

Referring to FIG. 1, a CVD apparatus 10 includes a chamber 20 having an internal space, a susceptor 100 disposed within the chamber 20, which is rotatable and is configured to receive a plurality of substrates 30 thereon, a heating unit 40 disposed under the susceptor 100 to provide heat, and a gas inlet 50 extending from an upper surface of the chamber 20 to an upper portion of the susceptor 100.

The chamber 20 may have a cylindrical structure, which provides an internal space having a dimension to cause a chemical vapor reaction between a reactive gas introduced thereto through the gas inlet 50 and the substrates 30 as deposition targets, and thus to allow an epitaxial layer to be, for example, deposited and grown on upper surfaces of the substrates 30.

The chamber 20 may be formed of a metal having excellent abrasion resistance and/or corrosion resistance. A heat insulator may be provided on an inner surface of the chamber to tolerate a high temperature atmosphere.

The susceptor 100, on which at least one substrate 30 is mounted, and the heating unit 40 may be provided in the chamber 20. An exhaust (not shown), which discharges gases remaining after a chemical vapor reaction with the substrate 30, may be provided.

The gas inlet 50 may have a shower head type structure and may be provided on an upper portion of the internal space of the chamber 20. Accordingly, a reactive gas may be vertically jet-sprayed onto the susceptor 100 rotating under the gas inlet 50.

Alternatively, the gas inlet 50 may have a planar structure along the circumference of a lateral end portion of the chamber 20. Accordingly, a reactive gas may be horizontally jet-sprayed from a peripheral portion of the chamber 20 to a central portion of the chamber 20 through a plurality of injection nozzles.

The heating unit 40 may be disposed under the susceptor 100, on which the substrate 30 is to be mounted, to heat the substrate 30 through the susceptor 100. The heating unit 40 may be any one of an electric heater, a high frequency induction heating unit, an infrared radiation heating unit, a laser, and the like.

A temperature sensor (not shown) may be provided in the chamber 20. The temperature sensor may be disposed in proximity to an outer surface of the susceptor 100 or the heating unit 40 to measure a temperature of an internal atmosphere of the chamber 20 and adjust a heating temperature based on measured values.

In the CVD apparatus 10, a source gas as a reactive gas and a carrier gas may be introduced to a central region of an upper surface of the susceptor 100 through the gas inlet 50, which extends close to the upper surface of the susceptor 100. For example, the introduced reactive gas may form a nitride thin film on the surface of the substrate 30 due to a chemical deposition reaction with the heated substrate 30. Residual gases and/or residual products may be discharged through the exhaust (not shown) arranged along wall surfaces of the chamber 20.

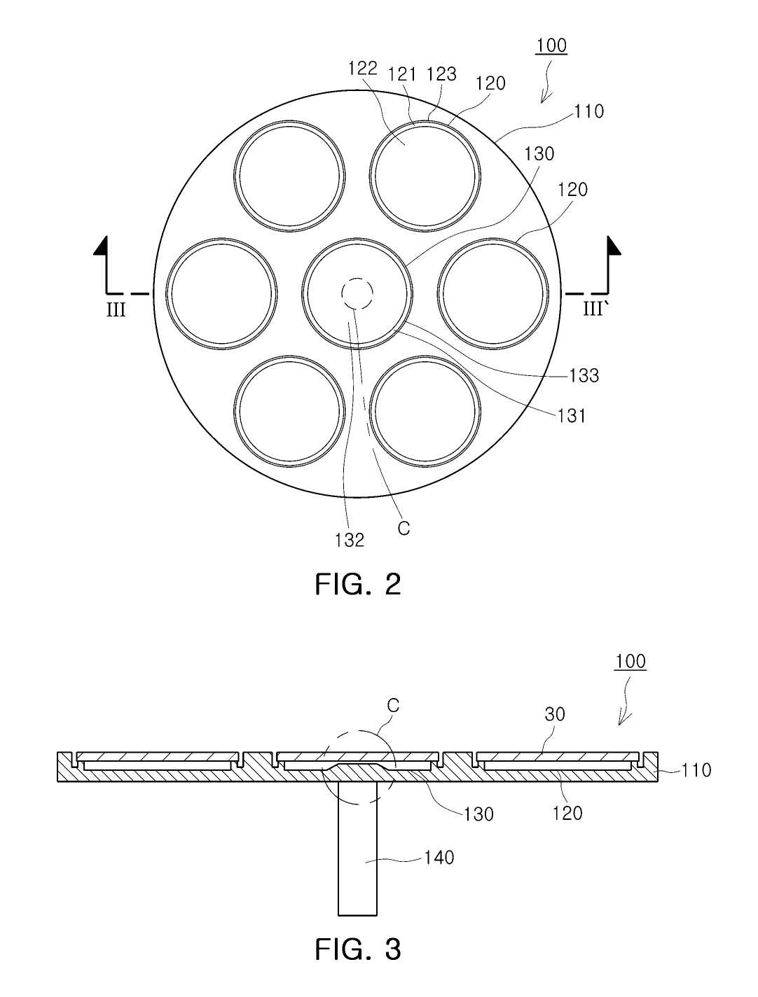

The structure of the susceptor 100 of FIG. 1 will be described in detail with reference to FIGS. 2 through 5.

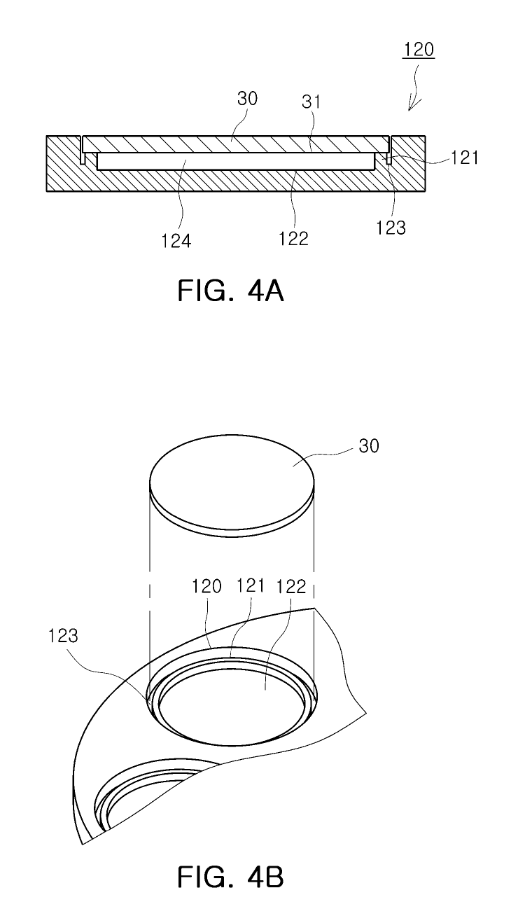

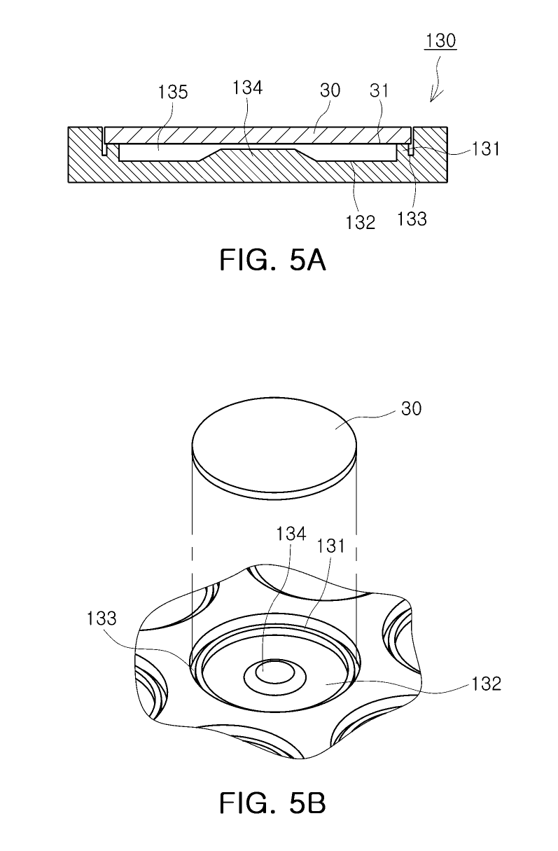

FIG. 2 is a plan view of a susceptor for the CVD apparatus of FIG. 1. FIG. 3 is a cross-sectional view of the susceptor of FIG. 2 taken along line III-III′. FIG. 4A is a cross-sectional view illustrating one of the first pockets, which are spaced apart from one another in a circumferential direction, on the susceptor of FIG. 2. FIG. 4B is an enlarged perspective view of the one first pocket of FIG. 4A. FIG. 5A is a cross-sectional view of a second pocket disposed at a central rotation surface (defined below) of the susceptor of FIG. 2. FIG. 5B is an enlarged perspective view of the second pocket of FIG. 5A.

Referring to FIGS. 2 and 3, the first susceptor 100 includes a rotor 110, a first pocket 120, a second pocket 130, and a rotational shaft 140.

In this example embodiment, a central rotation surface is defined as including a region under which a rotational shaft is formed to be coupled to a lower portion of the susceptor. Accordingly, the heating unit is not provided at the central rotation surface, e.g., a central portion of the rotor including a central rotation region C.

The rotor 110 may be formed of graphite with carbon or silicon carbide (SiC) coated thereon. Further, the rotor 110 may have a disk shape such that it is easily rotated within the chamber 200 in which a reactive gas is supplied.

A plurality of first pockets 120, on which the substrates 30 for chemically depositing a metal compound are to be mounted, may be provided at the same plane at intervals in a circumferential direction with respect to the rotational center of the rotor 110, and the second pocket 130 may be provided at the central rotation surface of the first rotor 110.

However, in the present inventive concepts, the disposition and/or number of the pockets are not limited to those illustrated in FIG. 2 and may be changed, for example, according to the diameter of a substrate.

For example, epitaxial layers may be grown by simultaneously rotating the plurality of substrates 30 in the first and second packets 120 and 130 of the first rotor 110.

A rotational shaft 140 may be coupled to a lower surface of the rotor 110 and connected to a driving device (not shown). Accordingly, when the rotational shaft 140 rotates in one direction according to driving of the driving device, the rotor 110 rotates in the same direction as the rotational shaft 140.

Because at least one of the first and second pockets 120 and 130 is provided at the upper surface of the rotor 110, the first and/or second pockets 120 and 130 may have a shape corresponding to the shape of the general annular substrates 30 and have a diameter greater than that of the substrate 30 such that the substrate 30 may be easily disposed and removed.

Referring to FIGS. 4A and 4B, the first pockets 120 disposed at intervals in the circumferential direction on the susceptor for a CVD apparatus include a first mounting portion 121, a first recess portion 122, and a first groove portion 123, respectively. The substrate 30 may be mounted on the first mounting portion 121 of the first pocket 120 to have an epitaxial layer grown thereon.

Portions of the first pocket 120, other than the first mounting portion 121, may not be in contact with the substrate 30. The first mounting portion 121 may have a contact surface and may be in contact with the substrate 30 at the contact surface. The first mounting portion 121 may have a portion protruding from a lower surface of the first pocket 120 and may have an annular shape having the same center as that of the first pocket 120. An inner side wall and/or an outer side wall of the first mounting portion 121 may be perpendicular with respect to the substrate 30, but the present inventive concepts are not limited thereto. For example, both side walls of the first mounting portion 121 may be sloped such that a contact area between the first mounting portion 121 and the substrate 30 is reduced.

The first recess portion 122 having a circular shape may be formed to be recessed and provided at an inner side of the first mounting portion 121. Accordingly, an air gap 124 may be formed to have a space between a bottom surface of the first recess portion 122 of the first pocket 120 on which a substrate is mounted and a lower surface 31 of the substrate 30 such that the substrate 30 mounted on the first mounting portion 121 can be uniformly heated. For example, when heat is applied by the heating unit 40, the substrate 30 provided on the first pocket 120 can be uniformly heated across the entire region of the substrate 30.

The annular first groove portion 123 may be formed at an outer side of the first mounting portion 121. The annular first groove portion 123 may be formed to have a depth along outer edges of the first mounting portion 121 such that, after completing a process, e.g., a deposition process, on the substrate 30, the substrate 30 can be easily separated and released from the first pocket 120.

Referring to FIGS. 5A and 5B, the second pocket 130 provided on the central rotation surface of the susceptor of FIG. 2 includes a second mounting portion 131, a second recess portion 132, and a second groove portion 133. The substrate 30 may be mounted on the second mounting portion 131 of the second pocket 130 to have an epitaxial layer grown thereon.

Portions of the second pocket 130, other than the second mounting portion 131, may not be in contact with the substrate 30. The second mounting portion 131 may have a contact surface and may be in contact with the substrate 30 at the contact surface. The second mounting portion 131 has a portion protruding from a lower surface of the second pocket 130 and may have an annular shape having the same center as that of the second pocket 130. An inner side wall and/or an outer side wall of the second mounting portion 131 may be perpendicular with respect to the substrate 30, but the present inventive concepts are not limited thereto. For example, both side walls of the first mounting portion 131 may be sloped such that a contact area between the first mounting portion 121 and the substrate 30 is reduced.

The second recess portion 132 having a circular shape may be formed to be recessed and provided at an inner side of the second mounting portion 131.

Because the first rotational shaft 140 for rotatably driving the first rotor 110 is coupled to a lower portion of the second pocket 130 at the central rotation surface including the central rotation region C, the heating unit 40 providing heat to the first susceptor 100 including the first rotor 110 cannot be provided at the central rotation surface. Thus, a temperature of the substrate 30 corresponding to the central portion of the second pocket 130, e.g., the central rotation surface, is relatively low.

To uniformly heat the substrate 30 mounted on the second mounting portion 131, a bottom surface of the second pocket 130 may be formed such that heat transmission to the central rotation region C can be improved. For example, an interval between a bottom surface of the second recess portion 132 of the second pocket 130 and the lower surface 31 of the substrate 30 in the central rotation region C may be formed to be smaller than that between the bottom surface of the second recess portion 132 of the second pocket 130 and the lower surface 31 of the substrate 30 in regions other than the central rotation region C.

In detail, a protruding portion 134 may be formed in the second recess portion 132 of the second pocket 130 such that it is protruding from the bottom surface of the second recess portion 132 in the region, in which the heating unit 40 is not positioned, e.g., the central rotation region C. For example, the protruding portion 134 may be a convex portion.

For example, the protruding portion 134 may be formed to have a flat upper surface, and side walls thereof may be formed to have a slope such that the interval between the bottom surface of the second recess portion 132 of the second pocket 130 and the lower surface 31 of the substrate 30 increases in a direction from the center of the second recess portion 132 towards edge thereof. However, the present inventive concepts are not limited thereto.

For example, the interval between the bottom surface of the second recess portion 132 and the lower surface 31 of the substrate 30 in the region of the second recess portion 132 of the second pocket 130 in which the heating unit 40 is not positioned, e.g., the central rotation region C, may be formed to be smaller than the interval 135 at a position of the second pocket 130, in which the protruding portion 134 is not provided because the heating unit 40 is positioned thereunder.

When the interval between the bottom surface of the second recess portion 132 and the lower surface 31 of the substrate 30 in the central rotation region C and that in the peripheral region are different, heat transmission to the substrate 30 may be more effective at a portion in which the interval is relatively small. For example, ineffective heating of the substrate 30 at the central rotation region C due to the absence of the heating unit 40 thereunder may be compensated by enhanced heat transmission to the substrate 30 due to the smaller interval implemented by the protruding portion 134. Accordingly, the substrate 30 can be uniformly heated across the entire region of the substrate 30.

In the related art, a pocket may not be provided on the central rotation surface of the susceptor for a CVD apparatus due to a temperature difference at the central rotation surface of the susceptor. In the present embodiment, however, a pocket can be provided even on the central rotation surface, thereby enhancing productivity.

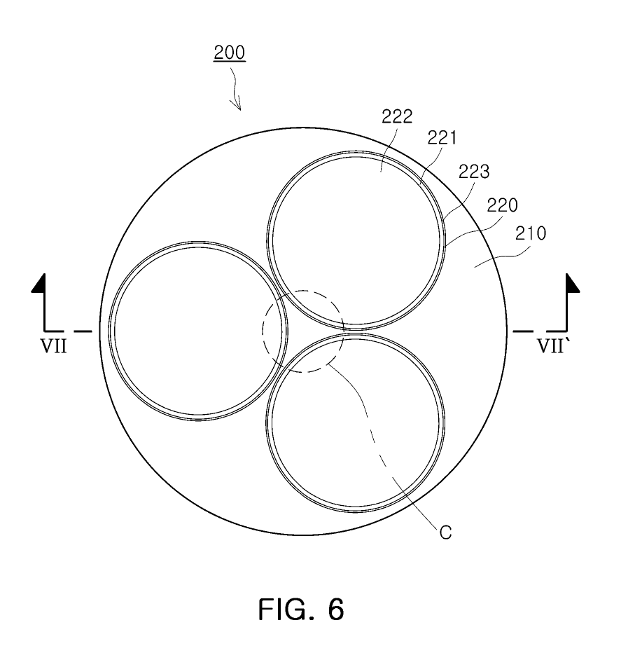

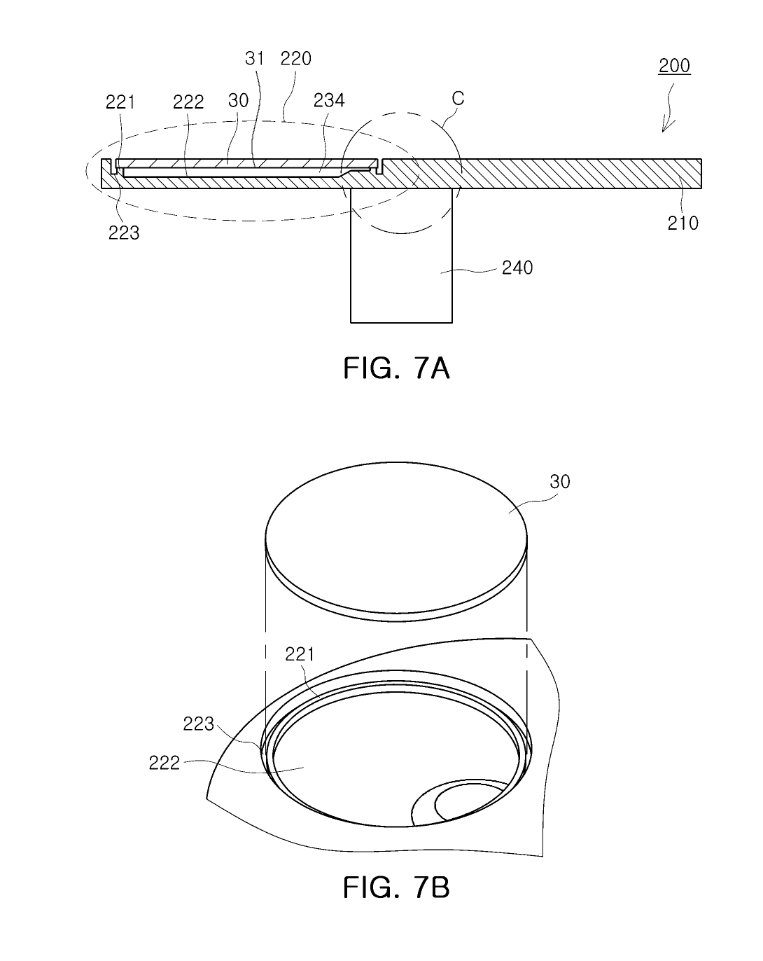

FIG. 6 is a plan view of a susceptor for a CVD apparatus according to an example embodiment. FIG. 7A is a cross-sectional view of the susceptor of FIG. 6 taken along line VII-VII′. FIG. 7B is an enlarged perspective view of a third pocket of the susceptor of FIG. 7A.

Referring to FIGS. 6 to 7B, a susceptor 200 includes a rotor 210, a third pocket 220, and a rotational shaft 240.

A plurality of third pockets 220, on which the substrates 30 for chemically depositing a metal compound are to be placed, are provided on the same surface of the rotor 210. In this embodiment, the third pockets 220 may be formed to have a diameter extending to the rotational central region C, in which the rotational shaft 240 is coupled to the central portion of the rotor 210.

However, the present inventive concepts are not limited to the disposition and/or number of the pockets illustrated in FIG. 6. For example, the disposition and number of the pockets may be changed according to the diameter of the substrate.

For example, epitaxial layers may be grown by simultaneously rotating the plurality of substrates 30 in the third pockets 220 of the rotor 210.

The rotational shaft 240 connected to a driving device (not shown) may be coupled to a lower surface of the rotor 210. Accordingly, when the rotational shaft 240 rotates in one direction according to driving of the driving device, the rotor 210 rotates in the same direction as the rotational shaft 240.

The third pockets 220 may have a shape corresponding to the shape of the general annular substrates 30 and have a diameter greater than that of the substrate 30 such that the substrate 30 may be easily disposed and removed.

Referring to FIGS. 7A and 7B, the third pockets provided on the susceptor may include a third mounting portion 221, a third recess portion 222, and a third groove portion 223, respectively. The substrate 30 may be mounted on the third mounting portion 221 of the third pocket 220 to have an epitaxial layer grown thereon.

Portions of the third pocket 220, other than the third mounting portion 221, may not be in contact with the substrate 30. The third mounting portion 221 may have a contact surface and may be in contact with the substrate 30 at the contact surface. The third mounting portion 221 may have a portion protruding from a lower surface of the third pocket 220 and may have an annular shape having the same center as that of the third pocket 220. An inner side wall and/or an outer side wall of the third mounting portion 221 may be perpendicular with respect to the substrate 30, but the present inventive concepts are not limited thereto. For example, both side walls of the third mounting portion 221 may be sloped such that a contact area between the third mounting portion 221 and the substrate 30 is reduced.

The third recess portion 222 having a circular shape may be formed to be recessed and provided at an inner side of the third mounting portion 221. To uniformly heat the substrates 30 mounted on the third mounting portions 221, the bottom surfaces of the third pockets 220 on which the substrates 30 are mounted may be formed such that heat may be properly transmitted to the central rotation region C. For example, an interval between a bottom surface of the third recess portion 222 and the lower surface 31 of the substrate 30 in the central rotation region C may be formed to be smaller than an interval 234 between the bottom surface of the third recess portion 222 and the lower surface 31 of the substrate 30 in regions other than the central rotation region C.

For example, the region C of the third recess portion 222 of the third pocket 220 in which the heating unit 40 is not positioned may be formed to have a portion protruding from the bottom surface of the third recess portion 222. The protruding portion may be formed to have a flat upper surface. Side walls of the protruding portion may be formed to be sloped such that the interval between the bottom surface of the third recess portion 222 of the third pocket 220 and the lower surface 31 of the substrate 30 decreases as the side walls get dose to the central rotation region C. However, the present inventive concepts are not limited thereto.

An annular third groove portion 223 may be formed at an outer side of the third mounting portion 221. The annular third groove portion 223 may be formed to have a depth along outer edges of the third mounting portion 221 such that, after completing a process, e.g., a deposition process, on the substrate 30, the substrate 30 can be easily separated and released from the third pocket 220.

When the interval between the bottom surface of the third recess portion 222 and the lower surface 31 of the substrate 30 in the central rotation region C and that in the peripheral region are different, heat transmission to the substrate 30 may be more effective at a portion in which the interval is relatively small. For example, ineffective heating of the substrate 30 at the central rotation region C due to the absence of the heating unit 40 thereunder may be compensated by enhanced heat transmission to the substrate 30 due to the smaller interval implemented by the protruding portion. Accordingly, the substrate 30 can be uniformly heated across the entire region of the substrate.

According to example embodiments of the inventive concepts, the interval between the bottom surface of the pocket on which a substrate is to be mounted and a lower surface of the substrate in the susceptor for a CVD apparatus may be adjusted to achieve a relatively uniform temperature distribution across the entire region of the substrate, thereby improving quality of a fabrication process involved.

In addition, productivity also can be enhanced because the number of substrates mounted on the susceptor for a CVD apparatus can be increased.

While the present inventive concepts have been shown and described in connection with the embodiments, it will be apparent to those skilled in the art that modifications and variations can be made without departing from the spirit and scope of the inventive concepts as defined by the appended claims.

What is claimed is:

1. A chemical vapor deposition (CVD) apparatus comprising:
a chamber;
a susceptor in the chamber, the susceptor including,
a rotor,
a rotational shaft coupled to a lower portion of the rotor,
a driving device coupled to the rotational shaft, the driving device configured to rotatably drive the rotational shaft, and
at least one pocket defined at an upper surface of the rotor, the at least one pocket including
a mounting portion configured to receive a substrate thereon, and
a protruding portion protruding from a bottom surface of the at least one pocket such that the protruding portion is positioned at a region corresponding to the rotational shaft; and
a heating unit under the susceptor, the heating unit surrounding the rotational shaft and configured to heat the substrate.

2. The CVD apparatus of claim 1, wherein an interval between the bottom surface of the pocket and the received substrate is smaller at the region corresponding to the rotational shaft than at regions not corresponding to the rotational shaft and being at an inner side of the mounting portion.

3. The CVD apparatus of claim 1, wherein an upper surface of the protruding portion is flat.

4. The CVD apparatus of claim 3, wherein side was of the protruding portion are sloped such that the interval between the substrate and the bottom surface of the pocket increases in a direction from a center of the pocket towards an edge thereof.

5. The CVD apparatus of claim 1, wherein the pocket includes an annular groove portion, the annular groove portion formed to have a depth along outer edges of the mounting portion.

6. The CVD apparatus of claim 1, wherein the rotor is a rotational structure made of graphite coated with carbon or silicon carbide (SiC).

7. The CVD apparatus of claim 1, wherein the mounting portion is a portion projecting from the bottom surface of the pocket.

8. The CVD apparatus of claim 1, wherein the mounting portion has an annular shape, a center of the mounting portion is the same as that of the pocket.

9. The CVD apparatus of claim 1, wherein the heating unit is any one selected from the group consisting of an electric heater, a high frequency induction heating unit, an infrared radiation heating unit, and a laser.

10. The CVD apparatus of claim 1, wherein a pocket, among the at least one pocket, under which the rotational shaft is not positioned is formed such that an interval between a bottom surface of the pocket and the received substrate is uniform across the pocket at an inner side of the mounting portion.

11. A semiconductor manufacturing apparatus comprising:
a rotor including a plurality of pockets at a first surface, each of the plurality of pockets having a mounting portion configured to receive a substrate thereon;
a rotational shaft coupled to the rotor at a center portion of a second surface of the rotor, the second surface being opposite to the first surface, the rotational shaft configured to rotate the rotor, at least one of the plurality of pockets having a protruding portion from a bottom surface of the pocket such that the protruding portion at least partially overlaps the rotational shaft in a vertical direction; and
a heating unit configured to heat the substrate.

12. The semiconductor manufacturing apparatus of claim 11, wherein some of the plurality of pockets surrounds and overlaps with the rotational shaft in a vertical direction.

13. The semiconductor manufacturing apparatus of claim 11, wherein an upper surface of the protruding portion is flat.

14. The semiconductor manufacturing apparatus of claim 13, wherein side walls of the protruding portion are sloped such that an interval between the substrate and the bottom surface of the corresponding pocket decreases as the side walls get closer to the rotational shaft.

15. The semiconductor manufacturing apparatus of claim 11, wherein each of the plurality of pockets has a mounting portion at an edge thereof, the mounting portion projecting from the bottom surface of the pocket.

16. The semiconductor manufacturing apparatus of claim 15, wherein each of the plurality of pockets has a groove portion at an outer edge thereof, the groove portion is between the mounting portion and an edge of the pocket.
